(19) United States
(12) Patent Application Publication
(10) Pub. No.: US 2026/0372160 A1
(43) Pub. Date: Nov. 19, 2026

(54) SEMICONDUCTOR PACKAGE INCLUDING AN UNDERFILL MEMBER AND MANUFACTURING METHOD OF THE SEMICONDUCTOR PACKAGE

(71) Applicant: Samsung Electronics Co., Ltd., Suwon-si (KR)

(72) Inventors: Sungkyu Park, Suwon-si (KR); Boseok Kwon, Suwon-si (KR)

(21) Appl. No.: 19/412,167

(22) Filed: Dec. 8, 2025

(30) Foreign Application Priority Data
May 19, 2025 (KR) 10-2025-0064417

(51) Int. Cl. H10W 72/30; H10D 80/30; H10W 72/00; H10W 90/00; H10W 90/24

(52) U.S. Cl. CPC H10W 72/334; H10W 72/07338; H10W 72/07353; H10W 72/337; H10W 72/342; H10W 72/344; H10W 72/884; H10W 90/24; H10W 90/732; H10W 90/734; H10W 90/754; H10D 80/30

(57) ABSTRACT

A semiconductor package includes a substrate, semiconductor chips stacked on the substrate, wherein at least one chip includes an overhang portion protruding in a lateral direction, relative to a lower chip disposed directly below the at least one chip, a first adhesive member disposed on a lower surface of the at least one chip, a second adhesive member including a center portion disposed between an upper surface of the lower chip and the first adhesive member, a first portion extending onto the overhang portion of the at least one chip, and a second portion extending opposite to the first portion, wherein the first portion is below the overhang portion and the center portion is between the first portion and the second portion, and a bonding wire electrically connecting the plurality of semiconductor chips and the substrate.

### CROSS-REFERENCE TO RELATED APPLICATION(S)

This application claims benefit of priority to Korean Patent Application No. 10-2025-0064417 filed on May 19, 2025 in the Korean Intellectual Property Office, the disclosure of which is incorporated herein by reference in its entirety.

### BACKGROUND

The present inventive concept relates to a semiconductor package including an underfill member and a method for manufacturing the same.

With the development of the electronics industry, demand for high functionality, high speed, and miniaturization of electronic components is increasing. In accordance with this trend, a semiconductor packaging technology for stacking a plurality of semiconductor chips in a single package is being developed. As the number of semiconductor chips to be stacked increases, problems such as sagging, cracking, or the like, of an overhang portion, may occur, and adhesion between semiconductor chips may be reduced due to surface curvature of the semiconductor chips.

### SUMMARY

One of problems to be solved by the present inventive concept is to provide a semiconductor package with improved reliability.

According to an aspect to the present disclosure, a semiconductor package includes a substrate, a plurality of semiconductor chips stacked on the substrate in a vertical direction perpendicular to an upper surface of the substrate, wherein at least one chip among the plurality of semiconductor chips includes an overhang portion protruding in a lateral direction parallel to the upper surface of the substrate, relative to a lower chip disposed directly below the at least one chip, a first adhesive member disposed on a lower surface of the at least one chip, a second adhesive member including a center portion disposed between an upper surface of the lower chip and the first adhesive member, a first portion extending onto the overhang portion of the at least one chip, and a second portion extending opposite to the first portion, wherein the first portion is below the overhang portion and the center portion is between the first portion and the second portion, and a bonding wire electrically connecting the plurality of semiconductor chips and the substrate.

According to an aspect of the present disclosure, a semiconductor package includes a substrate, a plurality of semiconductor chips stacked on the substrate in a vertical direction perpendicular to an upper surface of the substrate, wherein the plurality of semiconductor chips includes a first chip, a second chip directly below the first chip, and a lower chip directly below the second chip, wherein the second chip has a first side surface spaced apart, in a first lateral direction parallel to the upper surface of the substrate, from the lower chip disposed directly below the second chip, and a second side surface spaced apart from the first side surface in a second lateral direction, opposite to the first lateral direction, a first adhesive member including a center portion disposed between the lower chip and the second chip, a first portion protruding in the first lateral direction, relative to the lower chip, and a second portion protruding in the second lateral direction, relative to the second chip, wherein the center portion is between the first portion and the second portion, and a bonding wire electrically connecting the plurality of semiconductor chips and the substrate.

According to an aspect of the present disclosure, a semiconductor package includes a substrate, a plurality of semiconductor chips stacked on the substrate in a vertical direction perpendicular to an upper surface of the substrate, wherein at least one chip among the plurality of semiconductor chips includes an overhang portion protruding in a lateral direction parallel to the upper surface of the substrate, relative to a lower chip disposed directly below the at least one chip, an attachment member disposed between the at least one chip and the lower chip, an underfill member disposed between the attachment member and the lower chip, and extending onto the overhang portion of the at least one chip, and a bonding wire electrically connecting the plurality of semiconductor chips and the substrate. The lower chip includes upper patterns and a passivation layer covering the upper patterns. At least a portion of a surface of the passivation layer includes a concave portion between the upper patterns. The underfill member is disposed in the concave portion.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a perspective view of a semiconductor package according to an example embodiment, and FIG. 1B is a cross-sectional side view of a semiconductor package according to an example embodiment.

FIG. 2 is a perspective view schematically illustrating surface curvature of a semiconductor chip.

FIGS. 3A and 3B are partial enlarged views of semiconductor packages according to implementation examples, and FIG. 3C is a partial enlarged view illustrating a semiconductor package of a comparative example.

FIGS. 4A, 4B, 4C, 4D and 4E are views illustrating a method for manufacturing a semiconductor package according to an example embodiment.

FIG. 5A is a perspective view of a semiconductor package according to an example embodiment, and FIG. 5B is a cross-sectional side view of a semiconductor package according to an example embodiment.

FIG. 6A is a perspective view of a semiconductor package according to an example embodiment, and FIG. 6B is a cross-sectional side view of a semiconductor package according to an example embodiment.

FIG. 7A is a perspective view of a semiconductor package according to an example embodiment, and FIG. 7B is a cross-sectional side view of a semiconductor package according to an example embodiment.

FIGS. 8A, 8B, and 8C are views illustrating a method for manufacturing a semiconductor package according to an example embodiment.

FIG. 9A is a perspective view of a semiconductor package according to an example embodiment, and FIG. 9B is a cross-sectional side view of a semiconductor package according to an example embodiment.

FIG. 10A is a perspective view of a semiconductor package according to an example embodiment, and FIG. 10B is a cross-sectional side view of a semiconductor package according to an example embodiment.

FIG. 11A is a perspective view of a semiconductor package according to an example embodiment, and FIG. 11B is a cross-sectional side view of a semiconductor package according to an example embodiment.

FIGS. 12A, 12B, and 12C are views illustrating a method of manufacturing a semiconductor package according to an example embodiment.

FIG. 13A is a perspective view of a semiconductor package according to an example embodiment, and FIG. 13B is a cross-sectional side view of a semiconductor package according to an example embodiment.

### DETAILED DESCRIPTION

Hereinafter, embodiments will be described with reference to the attached drawings as follows. Unless otherwise specifically stated, in the present specification, terms such as “on,” “upper portion,” “upper surface,” “lower portion,” “lower surface,” “side surface,” or the like may be based on the drawings, and may be actually changed, depending on a direction in which components are disposed.

In addition, ordinal numbers such as “first,” “second,” “third,” or the like may be used as labels for specific elements, operations, directions, or the like to distinguish between various elements, operations, directions, or the like. Terms that may not be described using “first,” “second,” or the like in the specification may still be referred to as “first” or “second” in the claims. In addition, terms that may be referenced by a specific ordinal number (e.g., “first” in a particular claim) may be described elsewhere by a different ordinal number (e.g., “second” in the specification or another claim).

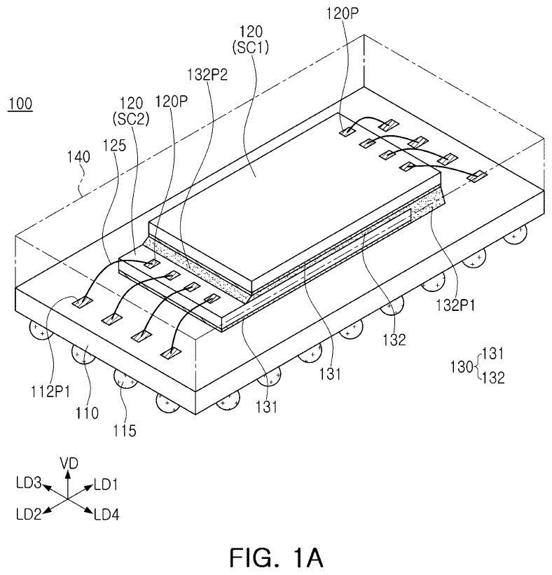

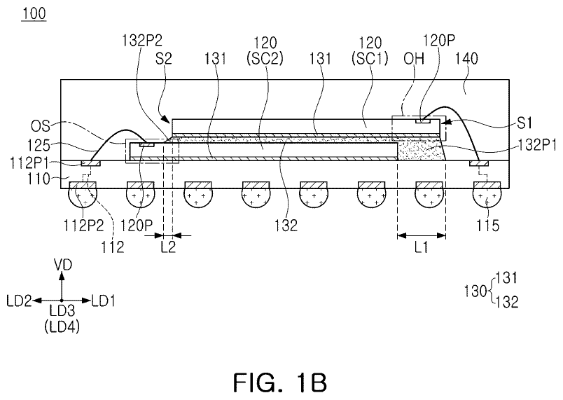

FIG. 1A is a perspective view of a semiconductor package 100 according to an example embodiment, and FIG. 1B is a cross-sectional side view of a semiconductor package 100 according to an example embodiment. For example, FIG. 1B illustrates the semiconductor package 100 of FIG. 1A as viewed from a third lateral direction LD3.

Referring to FIGS. 1A and 1B, the semiconductor package 100 according to an example embodiment may include a substrate 110, a plurality of semiconductor chips 120, and a plurality of adhesive members 130. According to an example embodiment, the semiconductor package 100 may further include a molded layer 140 (i.e., a mold layer).

According to example embodiments, an adhesive member 132 (hereinafter, referred to as “an underfill member” or “a second adhesive member”) in at least some of the plurality of adhesive members 130 may at least partially fill a gap between an overhang portion OH of a chip (e.g., an upper chip SC1) relatively located above and the substrate 110. For example, between the upper chip SC1 and a lower chip SC2, the underfill member 132 may include a gapfill portion 132P1 extending from the upper chip SC1 to the overhang portion OH of the upper chip SC1. The gapfill portion 132P1 of the underfill member 132 may support the overhang portion OH, thereby preventing occurrence of sagging and crack of the upper chip SC1, and improving reliability of the semiconductor package 100. In addition, the adhesive member 132 may fill surface curvature of the lower chip SC2, thereby preventing occurrence of voids between an attachment member 131 (hereinafter, referred to as a “first adhesive member”) and the lower chip SC2, and improving reliability of adhesion between the upper chip SC1 and the lower chip SC2. The surface curvature describes how a chip surface is convex (bulging up) or concave (bowed down) due to internal stress, thermal mismatch, or thin-film deposition. It may affect bonding uniformity or adhesive spreading in adhesive bonding. For example, the adhesive member 132 may fill a space defined by a curved surface of the lower chip SC2 to prevent the space from remaining as a void between the lower chip SC2 and the attachment member 131. In an embodiment, the adhesive member 132 may be conformally formed along the curved surface of the lower chip SC2 and provide a planarized surface.

The substrate 110 may be a substrate for semiconductor package including a printed circuit board (PCB), a ceramic substrate, a glass substrate, a tape wiring board, or the like. For example, the substrate 110 may be a double-sided PCB or a multilayer PCB.

The substrate 110 may include bonding pads 112P1, bump pads 112P2, and wiring 112 electrically connecting them. The bonding pads 112P1 may be disposed on an upper surface of the substrate 110, and the bump pads 112P2 may be disposed on a lower surface of the substrate 110. The bonding pads 112P1 and the bump pads 112P2 may include at least one metal or an alloy composed of two or more metals among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C).

Connection bumps 115 may be disposed below the bump pads 112P2. The connection bumps 115 may be electrically connected to the semiconductor chip 120 through the wiring 112. The connection bumps 115 may include, for example, tin (Sn) or an alloy including tin (Sn) (e.g., Sn—Ag—Cu). The connection bumps 115 may be electrically connected to an external device such as a module substrate, a system board, or the like.

The plurality of semiconductor chips 120 may be formed from a semiconductor wafer on which an integrated circuit (IC) is formed. The semiconductor wafer may include, for example, a semiconductor element such as silicon, germanium, or a semiconductor compound such as silicon carbide (SiC), gallium arsenide (GaAs), indium arsenide (InAs), and indium phosphide (InP). The plurality of semiconductor chips 120 may be bare semiconductor chips on which no separate bump or wiring layer is formed, but are not limited thereto, and may also be packaged type semiconductor chips. In an embodiment, each of the plurality of semiconductor chips may be one finished chip that results after the semiconductor wafer has been processed, tested, and diced into individual units.

The plurality of semiconductor chips 120 may include a non-volatile memory chip such as a flash memory, an electrically erasable programmable read-only memory (EEPROM), a phase-change random access memory (PRAM), a magnetoresistive random access memory (MRAM), a ferroelectric random access memory (FeRAM), or a resistive random access memory (RRAM), and/or a volatile memory chip such as dynamic random access memory (DRAM) or static random access memory (SRAM). The plurality of semiconductor chips 120 may include the same type of memory chip, but are not limited thereto. According to an embodiment, the plurality of semiconductor chips 120 may include different types of memory chips.

In some embodiments, the plurality of semiconductor chips 120 may include at least one logic chip, for example, a central processor (CPU), a graphics processor (GPU), a field programmable gate array (FPGA), an application processor (AP), a digital signal processor, an encryption processor, a microprocessor, a microcontroller, an analog-to-digital converter, an application-specific IC (ASIC), or the like. The plurality of semiconductor chips 120 may include the same type of semiconductor chip, but are not limited thereto. Depending on an embodiment, the plurality of semiconductor chips 120 may include different types of semiconductor chips.

The plurality of semiconductor chips 120 may be electrically connected to the bonding pad 112P1 of the substrate 110 through a bonding wire 125. The bonding wire 125 may connect a connection pad 120P of each of the plurality of semiconductor chips 120 to the bonding pad 112P1 of the substrate 110. The bonding wire 125 may include, but is not limited to, gold (Au), silver (Ag), lead (Pb), aluminum (Al), copper (Cu), or an alloy thereof. The connection pad 120P may include any one of copper (Cu), nickel (Ni), titanium (Ti), aluminum (Al), or an alloy thereof. The connection pad 120P may serve as a signal pad, a power pad, or a ground pad. The signal pad may provide a transmission/reception path for various signals, such as a data signal, an address signal, or the like, excluding a ground signal, a power signal, or the like.

The plurality of semiconductor chips 120 may be stacked in a vertical direction VD on the substrate 110. The plurality of semiconductor chips 120 may be attached to or mutually attached to the substrate 110 by the adhesive member 130. At least one semiconductor chip 120 among the plurality of semiconductor chips 120 may be offset from the others in a lateral direction parallel to an upper surface of the substrate 110 such that each connection pad 120P may be exposed. At least one chip among the plurality of semiconductor chips 120, for example, the upper chip SC1, may be shifted in a lateral direction from the lower chip SC2, for example, in a first lateral direction LD1 parallel to the upper surface of the substrate 110, such that the connection pad 120P of the lower chip SC2 directly below the upper chip SC1 may be exposed. In this case, the connection pad 120P may be exposed from an offset portion OS of the lower chip (e.g., SC2), and the bonding wire 125 connecting the lower chip SC2 and the substrate 110 may be spaced apart from the attachment member 131.

In an example embodiment, the upper chip SC1 may include an overhang portion OH protruding in the first lateral direction LD1 relative to the lower chip SC2 directly therebelow. For example, the overhang portion OH may extend beyond an edge of the lower chip SC2 in the first lateral direction LD1. The upper chip SC1 may have a first side surface S1 spaced apart from the lower chip SC2 in the first lateral direction LD1, and a second side surface S2 spaced apart from the first side surface S1 in a second lateral direction LD2, opposite to the first lateral direction LD1. The first side surface S1 may be one end of the overhang portion OH. The second side surface S2 of the upper chip SC1 may be spaced apart from the connection pad 120P of the lower chip SC2 in the first lateral direction LD1. The connection pad 120P of the lower chip SC2 may be disposed on the offset portion OS opposite to the overhang portion OH of the upper chip SC1. The connection pad 120P of the upper chip SC1 may be disposed on the overhang portion OH. The gapfill portion 132P1 of the underfill member 132 may support the overhang portion OH when the bonding wire 125 connects the upper chip SC1 to the substrate 110, thereby reducing deflection of the upper chip SC1 and preventing occurrence of sagging and crack.

The plurality of adhesive members 130 may be disposed on a lower surface of each of the plurality of semiconductor chips 120. The plurality of adhesive members 130 may adhere the plurality of semiconductor chips 120 stacked in the vertical direction VD. The plurality of adhesive members 130 may include a first adhesive member 131 and a second adhesive member 132. The first adhesive member 131 may be a die attach film (DAF) disposed on the lower surface of each of the plurality of semiconductor chips 120. In the present specification, the first adhesive member 131 may be referred to as an ‘attachment member’. The second adhesive member 132 may be disposed between the upper chip SC1 and the lower chip SC2, offset from each other, among the plurality of semiconductor chips 120. For example, when there are two or more pairs of upper chips SC1 and lower chips SC2, offset from each other, the second adhesive member 132 may be disposed between at least one pair of upper chips SC1 and lower chips SC2.

The first adhesive member 131 (hereinafter, referred to as a ‘attachment member’) may be an attachment film disposed on the lower surface of each of the semiconductor chips 120. The first adhesive member 131 may be a film including a synthetic resin such as an epoxy resin, a phenol resin, a melamine resin, a polyester resin, a silicone resin, a urethane resin, a polyamide resin, or an acrylic resin, for example. The first adhesive member 131 may include a DAF, but is not limited thereto. As described above, when the lower chip SC2 is offset from the upper chip SC1, the bonding wire 125 connecting the lower chip SC2 and the substrate 110 may be spaced apart from the first adhesive member 131. Compared to a structure in which the bonding wire 125 is partially embedded in the first adhesive member 131, a thickness of the first adhesive member 131 may be reduced, and a stacking height of the semiconductor chips 120 may be minimized. For example, a thickness, in a vertical direction VD, of the first adhesive member 131 may be in a range of about 5 μm or less, about 0.1 μm to about 5 μm, about 1 μm to about 5 μm, about 1 μm to about 3 μm, or the like.

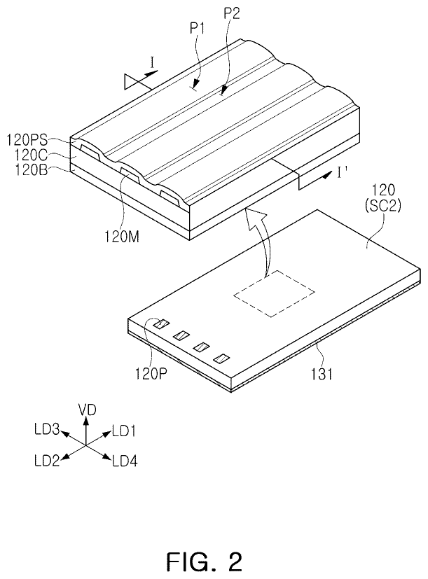

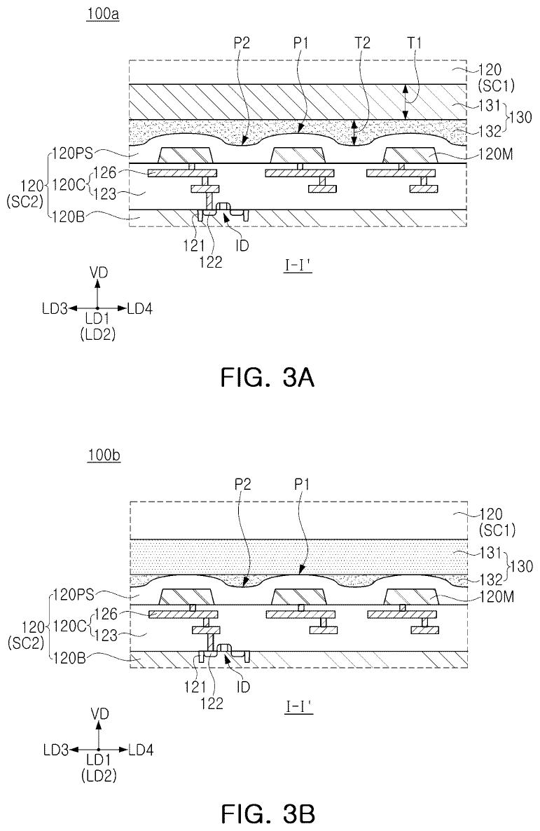

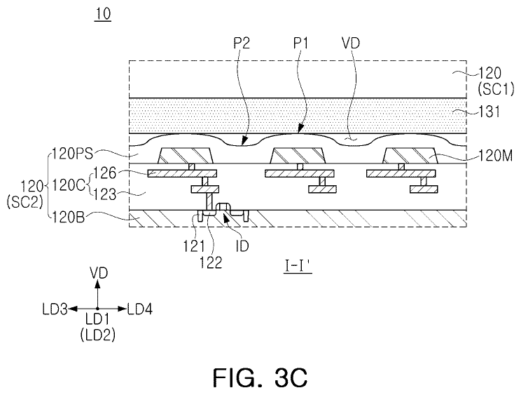

The second adhesive member 132 (hereinafter, ‘underfill member’) may be disposed between the at least one chip (hereinafter, ‘upper chip’) SC1 including the overhang portion OH and the lower chip SC2 directly therebelow. Unlike the first adhesive member 131, the second adhesive member 132 may be formed using a liquid adhesive. The second adhesive member 132 may be disposed between the first adhesive member 131 and the lower chip SC2, and may extend onto the overhang portion OH of the upper chip SC1. As described above, when the first adhesive member 131 is formed thinly (about 5 μm or less), adhesion of the first adhesive member 131 to the lower chip SC2 may be deteriorated due to the surface curvature of the lower chip SC2. In an example embodiment, the second adhesive member 132 may improve inter-chip adhesion by filling an empty space between the first adhesive member 131 and the lower chip SC2. This will be described later with reference to FIGS. 2 and 3A to 3C.

In an example embodiment, the second adhesive member 132 may include a first portion 132P1 protruding in the first lateral direction LD1 relative to the lower chip SC2. For example, the first portion 132P1 may extend beyond a side surface of the lower chip SC2 in the first lateral direction LD1. In the present specification, the first portion 132P1 may be referred to as a gapfill portion. The first portion 132P1 may extend onto the overhang portion OH of the upper chip SC1. The first portion 132P1 may fill a gap between the overhang portion OH and the substrate 110. The first portion 132P1 may fill a space between the first side surface S1, which may be one end of the overhang portion OH, and the lower chip SC2. The first portion 132P1 may support the overhang portion OH to reduce deflection of the upper chip SC1 and prevent occurrence of sagging and crack.

In an example embodiment, the second adhesive member 132 may further include a second portion 132P2 protruding in the second lateral direction LD2 relative to the upper chip SC1. The second portion 132P2 may be a portion extending in an opposite direction of the first portion 132P1. The second portion 132P2 may extend onto the offset portion OS of the lower chip SC2. The second portion 132P2 may protrude in the second lateral direction LD2 relative to the second side surface S2 of the upper chip SC1. The second portion 132P2 may be spaced apart from the connection pad 120P of the lower chip SC2. In some embodiments, the second portion 132P2 may be in contact with the connection pad 120P of the lower chip SC2. The term “contact,” as used herein, refers to a direct connection (i.e., physical touching) unless the context indicates otherwise.

In an example embodiment, each of the first portion 132P1 and the second portion 132P2 of the second adhesive member 132 may have a side surface inclined in an outward direction. A first length L1 of the first portion 132P1 extending in the first lateral direction LD1 may be greater than a second length L2 of the second portion 132P2 extending in the second lateral direction LD2. For example, the first length L1 of the first portion 132P1 may correspond to a maximum length, in the first lateral direction LD1, of a first region of the second adhesive member 132 located in a non-overlapping space between the upper chip SC1 and the lower chip SC2. The first region may be adjacent to the first side surface S1 of the upper chip SC1. The second length L2 of the second portion 132P2 may correspond to a maximum length, in the second lateral direction LD2, of a second region of the second adhesive member 132 located in a non-overlapping space between the upper chip SC1 and the lower chip SC2. The second region may be adjacent to the second side surface S2 of the upper chip SC1. For example, the first portion 132P1 and the second portion 132P2 may be formed as the liquid adhesive squeezes out from an overlapping space between the upper chip SC1 and the lower chip SC2, a portion of the liquid adhesive spreading onto an upper surface of the lower chip SC2, corresponding to the second portion 132P2, and a portion of the liquid adhesive onto a side surface of the lower chip SC2 and a lower surface of the upper chip SC1, corresponding to the first portion 132P1. In an embodiment, the first length L1 may correspond to a length of a lower surface of the first portion 132P1 in the first lateral direction LD1, and the second length L2 may correspond to a length of a lower surface of the second portion 132P2 in the second lateral direction LD2. A thickness of the first portion 132P1 in the vertical direction VD may be greater than a thickness of the second portion 132P2 in the vertical direction VD. In an embodiment, a maximum thickness of the first portion 132P1 in the vertical direction VD may be greater than a maximum thickness of the second portion 132P2 in the vertical direction VD. In an embodiment, the first portion 132P1 and the second portion 132P2 may be in a non-overlapping space between the lower chip SC2 and the upper chip SC1 in the vertical direction VD, and a portion of the second adhesive member 132 disposed in an overlapping space between the lower chip SC2 and the upper chip SC1 in the vertical direction VD is referred to a center portion which is between the first portion 132P1 and the second portion 132P2.

The molded layer 140 may be disposed on the substrate 110. The molded layer 140 may cover the plurality of semiconductor chips 120 and the bonding wire 125. The molded layer 140 may include a thermosetting resin such as an epoxy resin, a thermoplastic resin such as a polyimide, or a resin in which an inorganic filler is impregnated into these resins, for example, a prepreg, an Ajinomoto build-up film (ABF), a flame resistant 4 (FR-4), bismaleimide triazine (BT), or an epoxy molding compound (EMC).

FIG. 2 is a perspective view schematically illustrating surface curvature (P1 and P2) of a semiconductor chip 120. FIG. 2 is a view illustrating surface curvature of the lower chip SC2 according to an example embodiment.

FIGS. 3A and 3B are partial enlarged views of semiconductor packages 100a and 100b according to implementation examples, and FIG. 3C is a partial enlarged view illustrating a semiconductor package 10 according to a comparative example. The comparative example presented in this specification is provided solely to highlight differences from embodiments of the present disclosure. The comparative example is not admitted as prior art against the present disclosure. FIGS. 3A and 3B illustrate a stack form of the upper chip SC1 and the lower chip SC2 using the first adhesive member 131 and the second adhesive member 132 in an I-I′ cross-section of FIG. 2. FIG. 3C illustrates a stack form of the upper chip SC1 and the lower chip SC2 using only the first adhesive member 131 in an I-I′ cross-section of FIG. 2.

Referring to FIGS. 2, 3A, and 3B, the semiconductor chip 120 may include a semiconductor layer 120B, a circuit layer 120C, and a passivation layer 120PS. The semiconductor chip 120 may have curvature formed on at least a portion of a surface of the passivation layer 120PS. In an example embodiment, at least a portion of an upper surface of the lower chip SC2 may include a convex portion P1 and a concave portion P2.

The semiconductor layer 120B may be a semiconductor wafer. The semiconductor layer 120B may include, for example, a semiconductor element such as silicon, germanium, or a compound semiconductor such as silicon carbide (SiC), gallium arsenide (GaAs), indium arsenide (InAs), or indium phosphide (InP). The semiconductor layer 120B may include an isolation region 121 and a conductive region 122. The isolation region 121 may be an element isolation structure having a shallow trench isolation (STI) structure, and may include silicon oxide. The conductive region 122 may be, for example, a well doped with impurities or a structure doped with impurities.

The circuit layer 120C may be disposed on the semiconductor layer 120B on which the conductive region 122 may be formed. The circuit layer 120C may include individual elements ID, an interlayer insulating layer 123, and a wiring structure 126. The individual elements ID may include, for example, a field-effect-transistor (FET) such as a planar FET, an FinFET, or the like, a memory element such as a flash memory, a DRAM, an SRAM, an EEPROM, a PRAM, an MRAM, an FeRAM, an RRAM, or the like, or a logic element such as an AND, an OR, a NOT, or the like. The present disclosure is not limited thereto. In an embodiment, the individual elements ID may correspond to various active elements and/or passive elements to constitute a large-scale integration (LSI) system, a complementary-metal-oxide semiconductor (CMOS) image sensor (CIS), and a MEMS.

The interlayer insulating layer 123 may be formed to cover the individual elements ID and the wiring structure 126, thereby electrically isolating the individual elements ID. The interlayer insulating layer 123 may include an inorganic insulating material, for example, at least one of silicon oxide (SiO) or silicon nitride (SiN). The interlayer insulating layer 123 may include a flowable oxide (FOX), a Tonen Silazen (TOSZ), an undoped silica glass (USG), a borosilica glass (BSG), a phosphosilaca glass (PSG), a borophosphosilica glass (BPSG), a plasma enhanced tetra ethyl ortho silicate (PETEOS), a fluoride silicate glass (FSG), a high density plasma (HDP) oxide, a plasma enhanced oxide (PEOX), a flowable CVD (FCVD) oxide, or a combination thereof. At least a portion of the interlayer insulating layer 123 surrounding the wiring structure 126 may be formed as a low-k dielectric layer. The interlayer insulating layer 123 may be formed using a chemical vapor deposition (CVD), a flowable-CVD process, or a spin coating process.

The wiring structure 126 may be disposed in the interlayer insulating layer 123. The wiring structure 126 may be formed as a multilayer structure including a plurality of wiring patterns and a plurality of vias, and may be formed of, for example, aluminum (Al), gold (Au), cobalt (Co), copper (Cu), nickel (Ni), lead (Pb), tantalum (Ta), tellurium (Te), titanium (Ti), tungsten (W), or a combination thereof. A barrier film (not illustrated) including titanium (Ti), titanium nitride (TiN), tantalum (Ta), or tantalum nitride (TaN) may be disposed between the wiring patterns and/or vias and the interlayer insulating layer 123. The wiring structure 126 may be electrically connected to the conductive region 122 and/or the individual elements ID. The wiring structure 126 may be connected to a connection pad 120P and upper patterns 120M. The upper patterns 120M may extend in the first lateral direction LD1 and the second lateral direction LD2, to connect the wiring structure 126 and the connection pads 120P.

The passivation layer 120PS may be disposed on an uppermost surface of the interlayer insulating layer 123, and may cover the connection pads 120P and the upper patterns 120M. The passivation layer 120PS may have an opening exposing at least a portion of the connection pads 120P. The passivation layer 120PS may include a single-layer insulating film or a multilayer insulating film. For example, the passivation layer 120PS may include an oxide film and/or a nitride film. In some embodiments, the passivation layer 120PS may include a photosensitive polyimide (PSPI). The passivation layer 120PS may include the convex portion P1 formed corresponding to shapes of the upper patterns 120M, and the concave portion P2 formed between the upper patterns 120M. The passivation layer 120PS may provide the upper surface of the lower chip SC2 including the convex portion P1 and the concave portion P2.

In example embodiments, the adhesive member 130 may be interposed between an upper chip SC1 and the lower chip SC2. The first adhesive member 131 may be disposed on a lower surface of the upper chip SC1. The second adhesive member 132 may be disposed between the first adhesive member 131 and the lower chip SC2. The second adhesive member 132 may be disposed in the concave portion P2 of the lower chip SC2. The second adhesive member 132 may fill a space between the concave portion P2 and the first adhesive member 131.

As illustrated in FIG. 3A, in an implementation example 100a, the second adhesive member 132 may cover the convex portion P1 and the concave portion P2. The first adhesive member 131 may be spaced apart from the convex portion P1 by the second adhesive member 132. A thickness T1 of the first adhesive member 131 may be in a range of about 5 μm or less, about 0.1 μm to about 5 μm, about 1 μm to about 5 μm, about 1 μm to about 3 μm, or the like. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range. A thickness T2 of the second adhesive member 132 on the concave portion P2 may be greater than or equal to a step difference between the convex portion P1 and the concave portion P2. For example, the thickness T2 of the second adhesive member 132 may be in a range of about 1 μm to about 5 μm, about 1 μm to about 4 μm, about 1 μm to about 3 μm, or the like. When the thickness T2 of the second adhesive member 132 exceeds about 5 μm, a total thickness of the adhesive member 130 may be unnecessarily increased. When the thickness T2 of the second adhesive member 132 is less than about 1 μm, a gap between the first adhesive member 131 and the concave portion P2 may not be sufficiently filled. However, the thickness T2 of the second adhesive member 132 may be designed in consideration of the step difference between the convex portion P1 and the concave portion P2.

As illustrated in FIG. 3B, in an implementation example 100b, the second adhesive member 132 may not cover the convex portion P1. The first adhesive member 131 may be in contact with the convex portion P1 of the passivation layer 120PS. The second adhesive member 132 may fill a gap between the first adhesive member 131 and the concave portion P2 of the passivation layer 120PS. A thickness T2 of the second adhesive member 132 filling the concave portion P2 may correspond to a step difference between the convex portion P1 and the concave portion P2. For example, the thickness T2 of the second adhesive member 132 may be in a range of about 1 μm to about 5 μm, about 1 μm to about 4 μm, about 1 μm to about 3 μm, or the like, but is not limited thereto.

The implementation examples 100a and 100b illustrated in FIGS. 3A and 3B may be implemented in separate semiconductor packages, respectively, or may be partially implemented in a single semiconductor package. For example, in an embodiment, the semiconductor package may include both the implementation example 100a of FIG. 3A and the implementation example 100b of FIG. 3B.

Referring to FIG. 3C, in a comparative example 10, an upper chip SC1 and a lower chip SC2 may be stacked only through a first adhesive member 131. As the thickness T1 of the first adhesive member 131 decreases (about 5 μm or less), a void VD may be formed between a concave portion P2 of a passivation layer 120PS and the first adhesive member 131. Therefore, adhesion and bonding between the passivation layer 120PS and the first adhesive member 131 may be reduced. As described above, according to an example embodiment, the second adhesive member 132 filling the concave portion P2 of the passivation layer 120PS may be introduced to prevent occurrence of voids VD and to improve bonding reliability between the upper chip SC1 and the lower chip SC2.

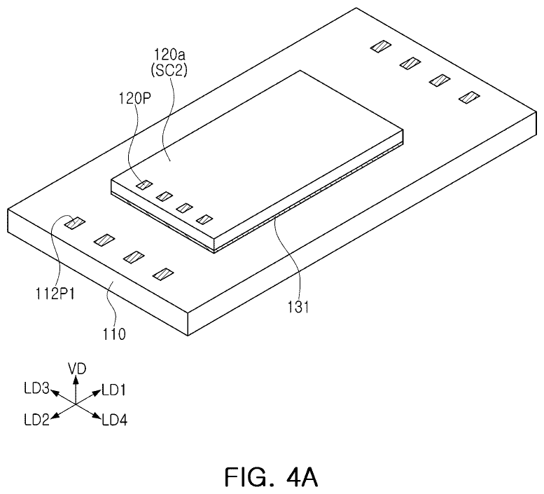

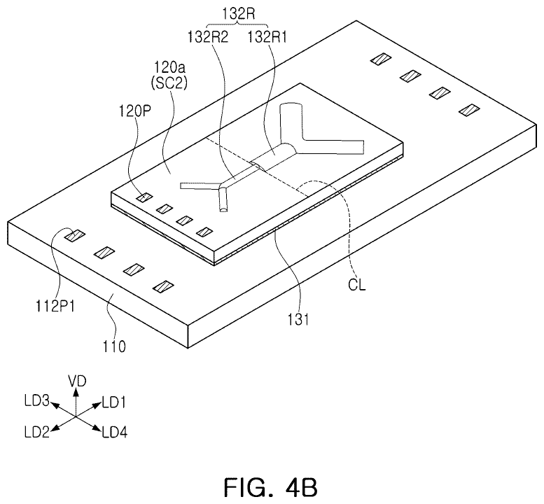

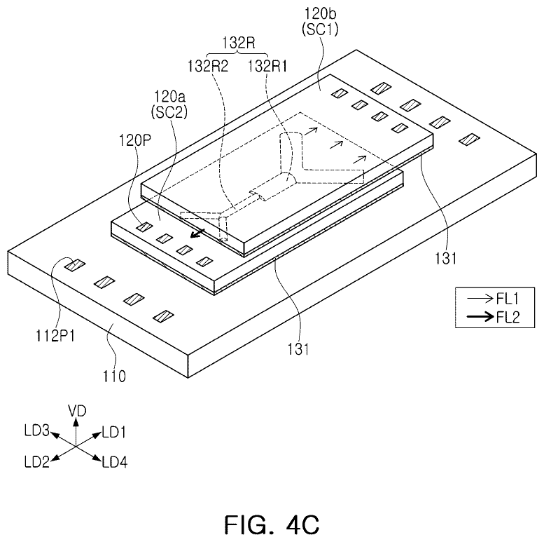

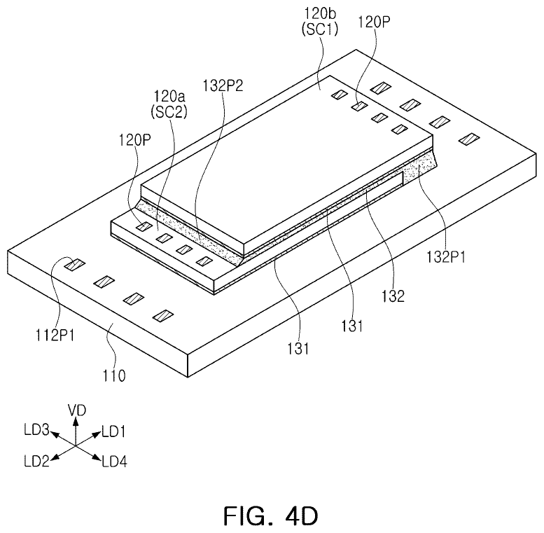

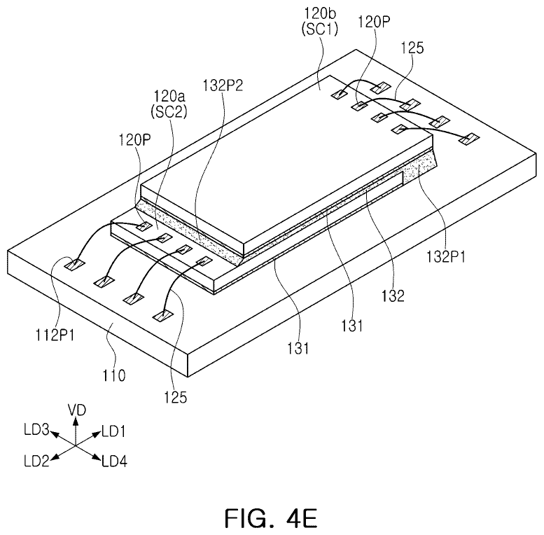

FIGS. 4A, 4B, 4C, 4D, and 4E are views illustrating a method of manufacturing a semiconductor package 100 according to an example embodiment.

Referring to FIG. 4A, a first semiconductor chip 120a may be attached to a substrate 110. The substrate 110 may be a strip substrate in which a plurality of unit substrate units illustrated in the drawing are connected. An attachment member 131 may be disposed between the substrate 110 and the first semiconductor chip 120a. The first semiconductor chip 120a may be fixed to the substrate 110 via the attachment member 131. The attachment member 131 may be a DAF attached to a lower surface of the first semiconductor chip 120a. The first semiconductor chip 120a may be the lower chip SC2, as described with reference to FIGS. 1A and 1B.

Referring to FIG. 4B, an adhesive material 132R may be applied on the first semiconductor chip 120a. The adhesive material 132R may include a liquid adhesive composition. The liquid adhesive composition may include a polymer binder such as an epoxy resin, a silicone resin, a polyimide, a polyurethane, an acrylic resin, or the like, and various additives (e.g., a curing agent, a filler, or the like.). The adhesive material 132R may include a heat-curable adhesive, an ultraviolet (UV)-curable adhesive, or the like. The adhesive material 132R may be a liquid adhesive having a viscosity of about 100 cP or more. The adhesive material 132R may be applied by a method such as dispensing, jet printing, screen printing, or the like.

In an example embodiment, the adhesive material 132R may be dispensed asymmetrically relative to a center line CL of the first semiconductor chip 120a. The adhesive material 132R may include a first distribution portion 132R1 and a second distribution portion 132R2, based on the center line CL. The first distribution portion 132R1 may be disposed on a side on which an overhang portion of an upper chip is formed in a subsequent process. The second distribution portion 132R2 may be disposed on a side on which a connection pad 120P of the first semiconductor chip 120a is disposed. The adhesive material 132R may be distributed more in the first distribution portion 132R1. In an embodiment, the first distribution portion 132R1 may include about 70% or more, for example, about 70% to about 90%, of a total distribution amount of the adhesive material 132R. When a distribution amount of the first distribution portion 132R1 is less than about 70%, the connection pad 120P of the first semiconductor chip 120a may be covered by the second distribution portion 132R2 before wire bonding in a subsequent process. Therefore, a flow region of the second distribution portion 132R2 may be limited to prevent the connection pad 120P from being covered before wire bonding of the first semiconductor chip 120a. When the distribution amount of the first distribution portion 132R1 exceeds about 90%, filling of the second distribution portion 132R2 and adhesion between the semiconductor chips may be deteriorated. The total distribution amount of the adhesive material 132R may be determined in consideration of a final thickness of an underfill member 132 to be formed in a subsequent process. In an embodiment, the center line CL may extend along a straight line extending in a direction such as a third lateral direction LD3 and a fourth lateral direction LD4 perpendicular to an offset direction of the first lateral direction LD1 and the second lateral direction LD2. In an embodiment, the center line CL may bisect the upper surface of the lower chip SC2 into two regions of equal area. The first distribution portion 132R1 may be applied to one of the two regions, and the second distribution portion 132R2 may be applied to the other of the two regions. To fill the gap between the upper chip SC1 and the substrate 110, the amount of the first distribution portion 132R1 may be greater than the amount of the second distribution portion 132R2.

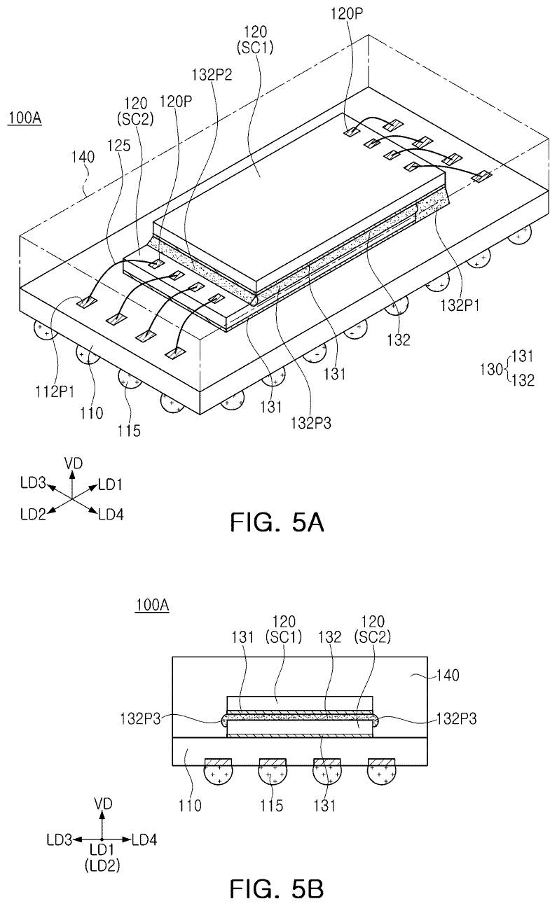

Referring to FIG. 4C, a second semiconductor chip 120b may be attached on the first semiconductor chip 120a. The second semiconductor chip 120b may be the upper chip SC1, as described with reference to FIGS. 1A and 1B. An attachment member 131 may be disposed on a lower surface of the second semiconductor chip 120b. The second semiconductor chip 120b provided with the attachment member 131 may be shifted in the first lateral direction LD1 such that a portion in which the connection pad 120P is disposed overhangs. The adhesive material 132R pressed by the second semiconductor chip 120b may spread in a lateral direction, for example, in the first lateral direction LD1 and the second lateral direction LD2. For example, the first distribution portion 132R1 may form a first flow FL1, and the second distribution portion 132R2 may form a second flow FL2. The first distribution portion 132R1 and the second distribution portion 132R2 may have a pattern shape for controlling the first flow FL1 and the second flow FL2, respectively. In the drawing, the first distribution portion 132R1 and the second distribution portion 132R2 may be formed in a ‘Y’ pattern, but are not limited thereto. Distribution amounts, pattern shapes, or the like of the first distribution portion 132R1 and the second distribution portion 132R2 may be determined to increase the first flow FL1 toward an overhang portion of the second semiconductor chip 120b. According to an embodiment, the adhesive material 132R may additionally form a flow in a third lateral direction LD3 and a flow in a fourth lateral direction LD4 (embodiment of FIGS. 5A and 5B).

Referring to FIG. 4D, the underfill member 132 may be formed between the first semiconductor chip 120a and the second semiconductor chip 120b. The underfill member 132 may be formed by curing a pressurized adhesive material 132R. In an embodiment, the underfill member 132 may be cured using a curing method to harden the liquid adhesive after the shifting of the second semiconductor chip 120b relative to the first semiconductor chip 120a such as thermal curing and UV curing. When the attachment member 131 is formed thinly (about 5 μm or less), the underfill member 132 may fill an empty space between the attachment member 131 and the first semiconductor chip 120a, thereby improving inter-chip adhesion.

The underfill member 132 may include a first portion 132P1 protruding in the first lateral direction LD1 relative to the first semiconductor chip 120a. The first portion 132P1 may extend onto an overhang portion of the second semiconductor chip 120b. The first portion 132P1 may fill a gap between the second semiconductor chip 120b and the substrate 110. The first portion 132P1 may reduce deflection of the second semiconductor chip 120b, and may prevent occurrence of sagging and cracking.

The underfill member 132 may further include a second portion 132P2 protruding in the second lateral direction LD2 relative to the second semiconductor chip 120b. The second portion 132P2 may be a portion extended opposite to the first portion 132P1. The second portion 132P2 may extend onto an offset portion of the first semiconductor chip 120a. The second portion 132P2 may be spaced apart from the connection pad 120P of the first semiconductor chip 120a.

Referring to FIG. 4E, the first semiconductor chip 120a and the second semiconductor chip 120b may be connected to the substrate 110 by a wire bonding process. The connection pads 120P of each of the first semiconductor chip 120a and the second semiconductor chip 120b may be connected to a bonding pad 112P1 of the substrate 110 through a bonding wire 125. The bonding wire 125 may include gold (Au) or an alloy thereof, but is not limited thereto. Thereafter, the molded layer and the connection bumps are formed, and then a sawing process may be performed to separate unit packages into individualized packages.

FIG. 5A is a perspective view of a semiconductor package 100A according to an example embodiment, and FIG. 5B is a cross-sectional side view of a semiconductor package 100A according to an example embodiment. For example, FIG. 5B illustrates the semiconductor package 100A of FIG. 5A as viewed from the third lateral direction LD3.

Referring to FIGS. 5A and 5B, in a semiconductor package 100A according to an example embodiment, a second adhesive member 132 may include a first portion and a second portion as described with reference to FIGS. 1A and 1B. The second adhesive member 132 may further include a third portion 132P3 extending in a horizontal direction (LD3 and LD4), perpendicular to a shift direction (e.g., LD1) along which an upper chip SC1 is shifted relative to a lower chip SC2. The semiconductor package 100A of the example embodiment may have the same or similar features as those described with reference to FIGS. 1A, 1B, 2, 3A, 3B, 3C, 4A, 4B, 4C, 4D and 4E, except for the third portion 132P3 of the second adhesive member 132. The third portion 132P3 of the second adhesive member 132 may protrude in at least one of the third lateral direction LD3 or the fourth lateral direction LD4 relative to the lower chip SC2.

In an example embodiment, the second adhesive member 132 may include a first portion 132P1 protruding in the first lateral direction LD1 relative to the lower chip SC2. The first portion 132P1 may fill a gap between an overhang portion of the upper chip SC1 and a substrate 110.

In an example embodiment, the second adhesive member 132 may further include a second portion 132P2 protruding in the second lateral direction LD2 relative to the upper chip SC1. The second portion 132P2 may extend onto an offset portion of the lower chip SC2.

In an example embodiment, the second adhesive member 132 may further include a third portion 132P3 protruding in at least one of the third lateral direction LD3 or the fourth lateral direction LD4 relative to the upper chip SC1 and/or the lower chip SC2. The third portion 132P3 may cover at least a portion of a side surface of the lower chip SC2. The third portion 132P3 may have a fillet shape protruding outwardly from the upper chip SC1 and/or the lower chip SC2. In some embodiments, the third portion 132P3 may extend onto an upper surface of the substrate 110. In this case, the third portion 132P3 may have a side surface inclined in an outward direction.

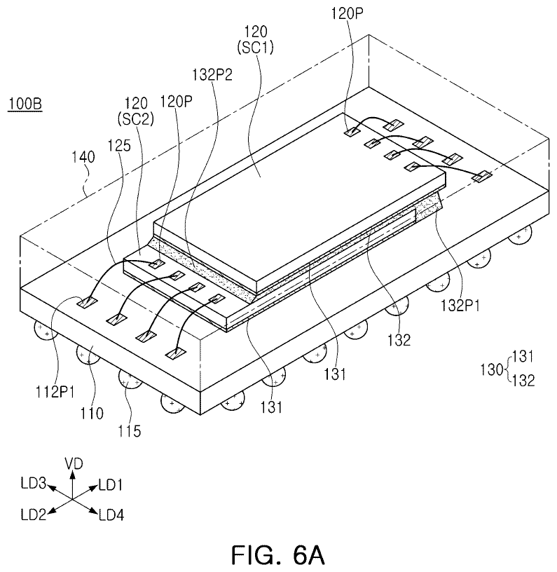

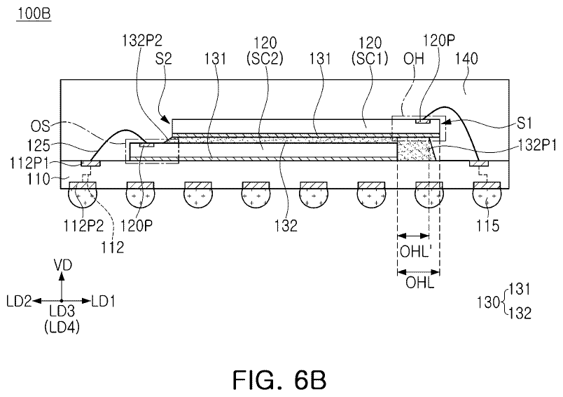

FIG. 6A is a perspective view of a semiconductor package 100B according to an example embodiment, and FIG. 6B is a cross-sectional side view of a semiconductor package 100B according to an example embodiment. For example, FIG. 6B illustrates the semiconductor package 100B of FIG. 6A as viewed from the third lateral direction LD3.

Referring to FIGS. 6A and 6B, in a semiconductor package 100B according to an example embodiment, a first portion 132P1 of a second adhesive member 132 may be in contact with a portion of an overhang portion OH of an upper chip SC1. The semiconductor package 100B of the example embodiment may have the same or similar features as those described with reference to FIGS. 1A, 1B, 2, 3A, 3B, 3C, 4A, 4B, 4C, 4D, 5A, and 5B, except for a shape of the first portion 132P1.

In an example embodiment, the second adhesive member 132 may include a first portion 132P1 protruding in the first lateral direction LD1 relative to a lower chip SC2. The first portion 132P1 may fill a gap between the overhang portion OH of the upper chip SC1 and a substrate 110. An edge of the overhang portion OH may be exposed from the first portion 132P1. A contact length OHL′ between the first portion 132P1 and the overhang portion OH in the first lateral direction LD1 may be smaller than a length OHL of the overhang portion OH in the first lateral direction LD1. In an example embodiment, a maximum distance in the first lateral direction LD1 between a side surface of the lower chip SC2 and a side surface of the first portion 132P1 may be smaller than the length OHL of the overhang portion OH which corresponds to a distance in the first lateral direction LD1 between the side surface of the lower chip SC2 and an imaginary surface extending in the vertical direction VD from the first side surface S1 of the upper chip SC1. In an embodiment, the overhang portion OH may extend beyond a side surface of the first portion 132P1 in the lateral direction LD1.

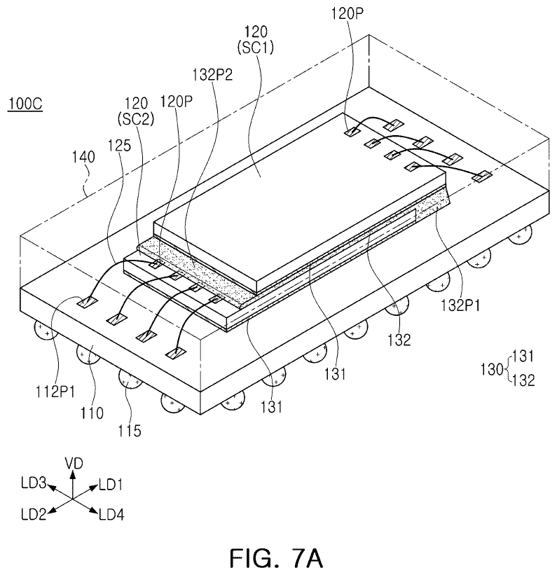

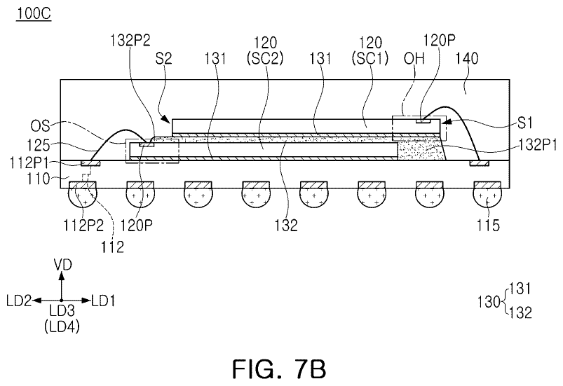

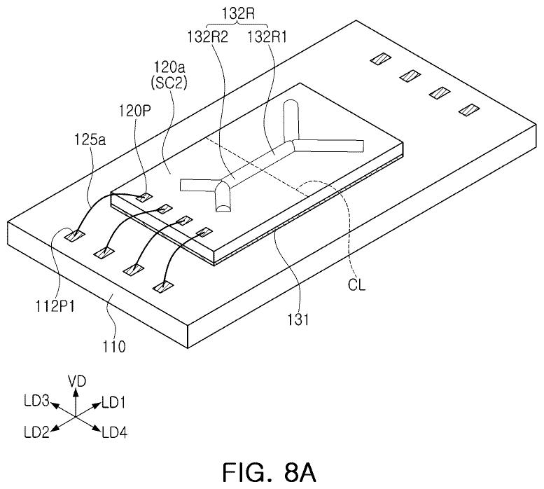

FIG. 7A is a perspective view of a semiconductor package 100C according to an example embodiment, and FIG. 7B is a cross-sectional side view of a semiconductor package 100C according to an example embodiment. For example, FIG. 7B illustrates the semiconductor package 100C of FIG. 7A as viewed from the third lateral direction LD3.

Referring to FIGS. 7A and 7B, in a semiconductor package 100C according to an example embodiment, a second portion 132P2 of a second adhesive member 132 may be in contact with a connection pad 120P of a lower chip SC2. The semiconductor package 100C of the example embodiment may have the same or similar features as those described with reference to FIGS. 1A, 1B, 2, 3A, 3B, 3C, 4A, 4B, 4C, 4D, 5A, 5B, 6A, and 6B, except for a covering region of the second portion 132P2.

In the example embodiment, the second adhesive member 132 may include the second portion 132P2 protruding in the second lateral direction LD2 relative to an upper chip SC1. The second portion 132P2 may extend onto an offset portion of the lower chip SC2. The second portion 132P2 may be formed after wire bonding of the lower chip SC2. The second portion 132P2 may cover at least a portion of the connection pad 120P of the lower chip SC2. In some embodiments, the second portion 132P2 may cover at least a portion of a bonding wire 125 connected to the connection pad 120P of the lower chip SC2.

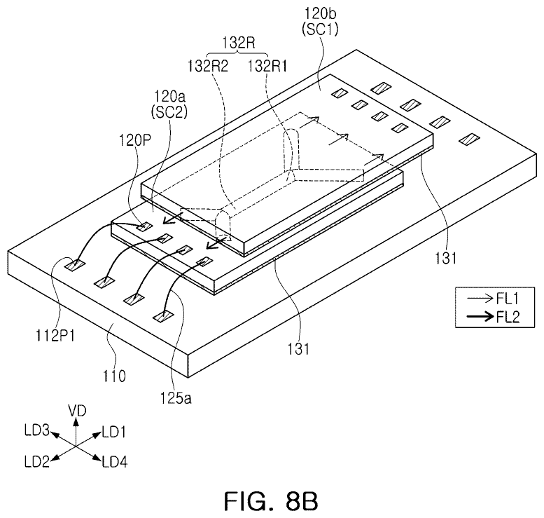

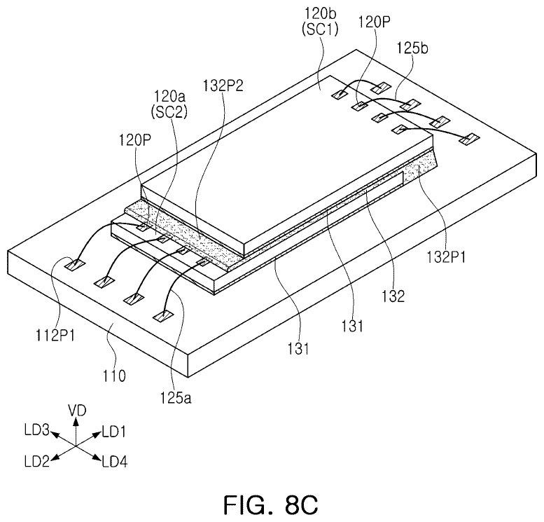

FIGS. 8A to 8C are views illustrating a method for manufacturing a semiconductor package 100C according to an example embodiment.

Referring to FIG. 8A, after forming a first bonding wire 125a connecting a first semiconductor chip 120a and a substrate 110, an adhesive material 132R may be applied on the first semiconductor chip 120a. The adhesive material 132R may include a liquid adhesive composition, as described with reference to FIG. 4B. The adhesive material 132R may be applied by a process such as dispensing, jet printing, screen printing, or the like. In an example embodiment, the adhesive material 132R may include a first distribution portion 132R1 and a second distribution portion 132R2, asymmetrically distributed relative to a center line CL of the first semiconductor chip 120a. The first distribution portion 132R1 may be disposed on a side on which an overhang portion of an upper chip is formed in a subsequent process. The second distribution portion 132R2 may be disposed on a side on which a connection pad 120P of the first semiconductor chip 120a is disposed. The adhesive material 132R may be distributed more on the first distribution portion 132R1. As in the present embodiment, when the first bonding wire 125a is already connected to a connection pad 120P, a total distribution amount of the adhesive material 132R may increase compared to an embodiment of FIGS. 1A and 1B, or the second distribution portion 132R2 exceeding about 30% of the total distribution amount of the adhesive material 132R may be formed. In a subsequent process, even when the second distribution portion 132R2 is in contact with the connection pad 120P or the first bonding wire 125a, connection reliability between the connection pad 120P and the first bonding wire 125a may be secured.

Referring to FIG. 8B, a second semiconductor chip 120b may be attached on the first semiconductor chip 120a. The second semiconductor chip 120b may be shifted in the first lateral direction LD1 such that a portion in which the connection pad 120P is disposed overhangs. The adhesive material 132R pressed by the second semiconductor chip 120b may spread in the first lateral direction LD1 and the second lateral direction LD2. The first distribution portion 132R1 may form a first flow FL1, and the second distribution portion 132R2 may form a second flow FL2. In the present embodiment, the second flow FL2 of the second distribution portion 132R2 toward the second lateral direction LD2 may increase compared to an embodiment of FIG. 4C.

Referring to FIG. 8C, an underfill member 132 may be formed between the first semiconductor chip 120a and the second semiconductor chip 120b. The underfill member 132 may include a first portion 132P1 protruding in the first lateral direction LD1 relative to the first semiconductor chip 120a. The first portion 132P1 may fill a gap between the second semiconductor chip 120b and the substrate 110. The underfill member 132 may further include a second portion 132P2 protruding in the second lateral direction LD2 relative to the second semiconductor chip 120b. The second portion 132P2 may cover at least a portion of the connection pad 120P of the first semiconductor chip 120a. In some embodiments, the second portion 132P2 may cover at least a portion of the first bonding wire 125a. Thereafter, a second bonding wire 125b may be formed, and a subsequent process may be performed.

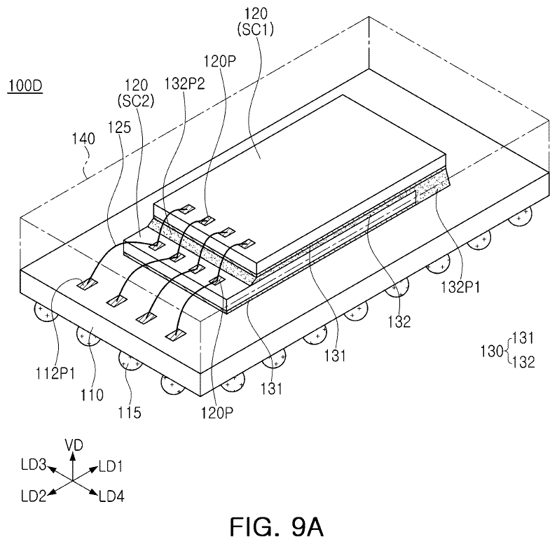

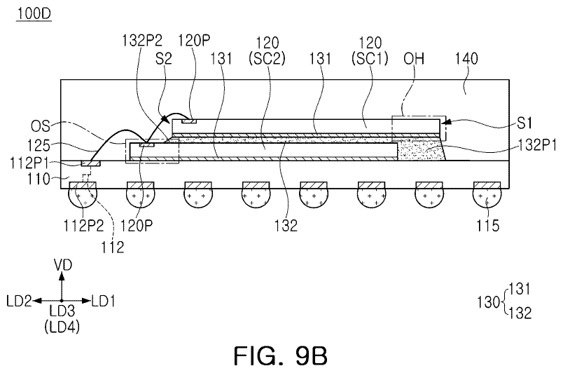

FIG. 9A is a perspective view of a semiconductor package 100D according to an example embodiment, and FIG. 9B is a cross-sectional side view of a semiconductor package 100D according to an example embodiment. For example, FIG. 9B illustrates the semiconductor package 100D of FIG. 9A as viewed from the third lateral direction LD3.

Referring to FIGS. 9A and 9B, in a semiconductor package 100D according to an example embodiment, a connection pad 120P of an upper chip SC1 may not be disposed in an overhang portion OH. The semiconductor package 100D of the example embodiment may have the same or similar features as those described with reference to FIGS. 1A, 1B, 2, 3A, 3B, 3C, 4A, 4B, 4C, 4D, 5A, 5B, 6A, 6B, 7A, 7B, 8A, 8B, and 8C, except for arrangement of the connection pad 120P of the upper chip SC1.

The upper chip SC1 may be shifted laterally, for example, in the first lateral direction LD1, such that the connection pad 120P of a lower chip SC2 directly therebelow may be exposed. The upper chip SC1 may have a first side surface S1 spaced apart from the lower chip SC2 in the first lateral direction LD1, and a second side surface S2 spaced apart from the first side surface S1 in the second lateral direction LD2, opposite to the first lateral direction LD1. The first side surface S1 may be one end of the overhang portion OH.

In an example embodiment, the connection pad 120P of the upper chip SC1 may be disposed to oppose the overhang portion OH. The connection pad 120P of the upper chip SC1 may be disposed adjacent to the second side surface S2 of the upper chip SC1. A first portion 132P1 of a second adhesive member may support the overhang portion OH of the upper chip SC1, thereby reducing deflection of the upper chip SC1 and preventing occurrence of sagging and crack.

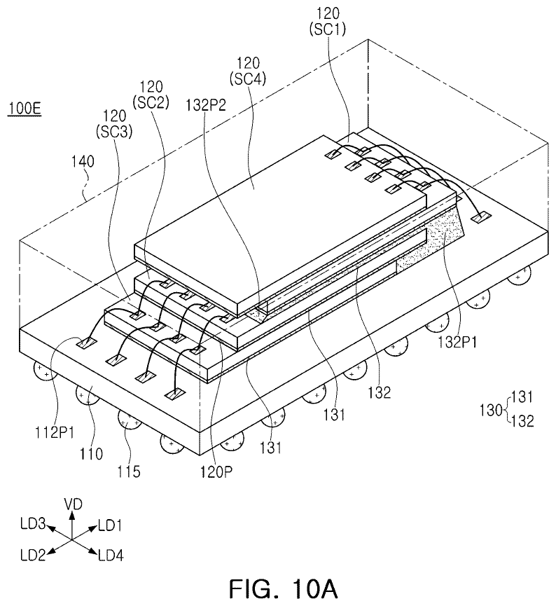

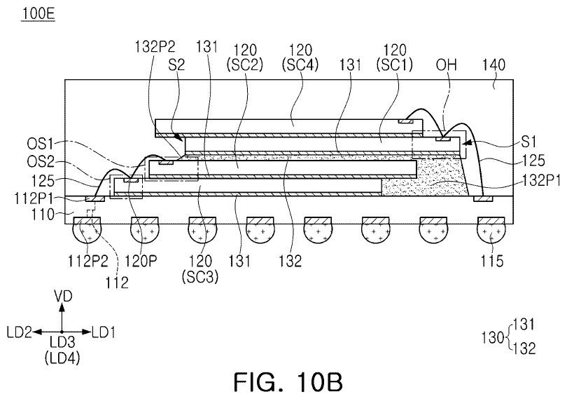

FIG. 10A is a perspective view of a semiconductor package 100E according to an example embodiment, and FIG. 10B is a cross-sectional side view of a semiconductor package 100E according to an example embodiment. For example, FIG. 10B illustrates the semiconductor package 100E of FIG. 10A as viewed from the third lateral direction LD3.

Referring to FIGS. 10A and 10B, in a semiconductor package 100E according to an example embodiment, a plurality of lower chips SC2 and SC3 may be disposed below an upper chip SC1. The semiconductor package 100E of the example embodiment may have the same or similar features as those described with reference to FIGS. 1A, 1B, 2, 3A, 3B, 3C, 4A, 4B, 4C, 4D, 5A, 5B, 6A, 6B, 7A, 7B, 8A, 8B, 8C, 9A, and 9B, except for arrangement of the lower chips SC2 and SC3. A plurality of semiconductor chips 120 may include two or more lower chips SC2 and SC3 stacked below the upper chip SC1. A first portion 132P1 of a second adhesive member 132 may be in contact with at least one side surface of each of the two or more lower chips SC2 and SC3.

The plurality of semiconductor chips 120 may include a first chip SC1 including an overhang portion OH, a second chip SC2 located directly below the first chip SC1, and a third chip SC3 located directly below the second chip SC2. The first chip SC1 may be shifted in the first lateral direction LD1 such that a connection pad 120P of the second chip SC2 may be exposed. The connection pad 120P may be exposed from a first offset portion OS1 of the second chip SC2. The second chip SC2 may be shifted in the first lateral direction LD1 such that a connection pad 120P of the third chip SC3 may be exposed. The connection pad 120P may be exposed from a second offset portion OS2 of the third chip SC3. The first chip SC1 may include the overhang portion OH protruding in the first lateral direction LD1 relative to the second chip SC2 and the third chip SC3.

The second adhesive member 132 may be disposed between the first chip SC1 and the second chip SC2. The second adhesive member 132 may improve adhesion between the first chip SC1 and the second chip SC2. The second adhesive member 132 may include a first portion 132P1 extending onto the overhang portion OH of the first chip SC1. A distribution amount of liquid adhesive may increase compared to the embodiment of FIGS. 1A and 1B such that the first portion 132P1 may fill a gap between the substrate 110 and the overhang portion OH of the first chip SC1 protruding in the first lateral direction LD1 relative to the second chip SC2 and the third chip SC3. For example, the first portion 132P1 may fill a gap between the overhang portion OH and the substrate 110 and a gap between the second chip SC2 and the substrate 110. The first portion 132P1 may support the overhang portion OH to reduce deflection of the upper chip SC1 and prevent occurrence of sagging and crack.

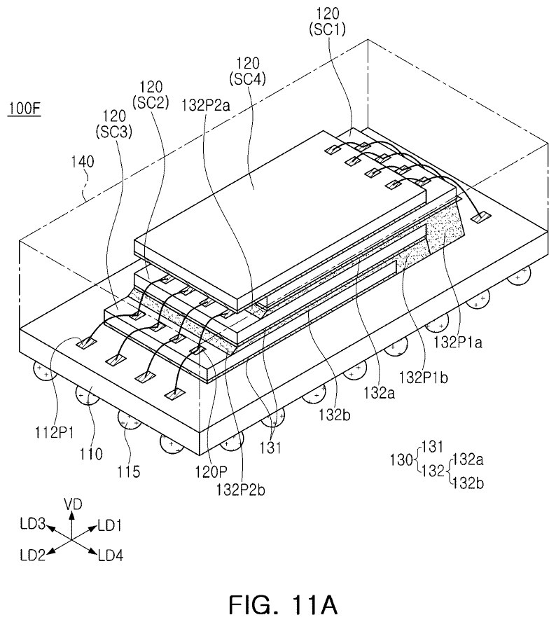

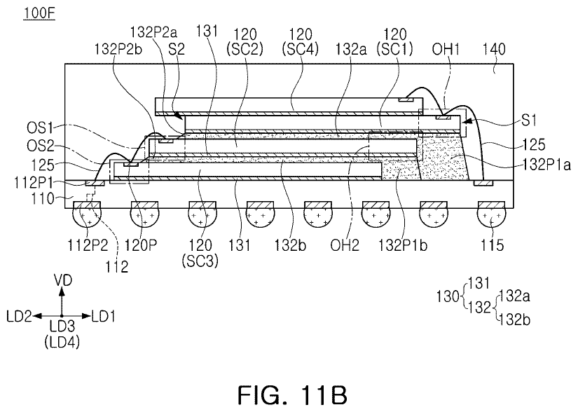

FIG. 11A is a perspective view of a semiconductor package 100F according to an example embodiment, and FIG. 11B is a cross-sectional side view of a semiconductor package 100F according to an example embodiment. For example, FIG. 11B illustrates the semiconductor package 100F of FIG. 11A as viewed from the third lateral direction LD3.

Referring to FIGS. 11A and 11B, in a semiconductor package 100F according to an example embodiment, a plurality of second adhesive members 132a and 132b corresponding to a plurality of lower chips SC2 and SC3 may be disposed below an upper chip SC1. The semiconductor package 100F of the example embodiment may have the same or similar features as those described with reference to FIGS. 1A, 1B, 2, 3A, 3B, 3C, 4A, 4B, 4C, 4D, 5A, 5B, 6A, 6B, 7A, 7B, 8A, 8B, 8C,9A, 9B, 10A, and 10B, except for arrangement of the second adhesive members 132a and 132b. A plurality of adhesive members 130 may include two or more second adhesive members 132a and 132b disposed on upper surfaces of two or more lower chips SC2 and SC3, respectively.

A plurality of semiconductor chips 120 may include a first chip SC1, a second chip SC2 located directly below the first chip SC1, and a third chip SC3 located directly below the second chip SC2. According to an embodiment, a fourth chip SC4 located directly above the first chip SC1 may be further included. The first chip SC1 may be shifted in the first lateral direction LD1 such that a connection pad 120P of the second chip SC2 may be exposed. The connection pad 120P may be exposed from a first offset portion OS1 of the second chip SC2. The second chip SC2 may be shifted in the first lateral direction LD1 such that a connection pad 120P of the third chip SC3 may be exposed. The connection pad 120P may be exposed from a second offset portion OS2 of the third chip SC3. The first chip SC1 may include a first overhang portion OH1 protruding in the first lateral direction LD1 relative to the second chip SC2 and the third chip SC3. The second chip SC2 may include a second overhang portion OH2 protruding in the first lateral direction LD1 relative to the third chip SC3. The first chip SC1 may have a first side surface S1 of the first overhang portion OH1 relative to the second chip SC2, and a second side surface S2 opposite thereto. The second chip SC2 may have a first side surface S1 of the second overhang portion OH2 relative to the third chip SC3, and a second side surface S2 opposite thereto.

A second adhesive member 132 may include an upper adhesive member 132a (or ‘first underfill member’) between the first chip SC1 and the second chip SC2, and a lower adhesive member 132b (or ‘second underfill member’) between the second chip SC2 and the third chip SC3. The first underfill member 132a may include a first portion 132P1a extending onto the first overhang portion OH1, and a second portion 132P2a extending onto the first offset portion OS1. The second underfill member 132b may include a first portion 132P1b extending onto the second overhang portion OH2, and a second portion 132P2b extending onto the second offset portion OS2.

The first portion 132P1a of the first underfill member 132a may protrude in the first lateral direction LD1 relative to the second chip SC2 and the third chip SC3. The first portion 132P1a of the first underfill member 132a may fill a space between the first overhang portion OH1 and a substrate 110. The first portion 132P1a of the first underfill member 132a may support the first overhang portion OH1 to prevent occurrence of sagging and crack of the first chip SC1. The first portion 132P1a of the first underfill member 132a may be in contact with at least one side surface of the second chip SC2 and at least one side surface of the first portion 132P1b of the second underfill member 132b.

The first portion 132P1b of the second underfill member 132b may protrude in the first lateral direction LD1 relative to the third chip SC3. The first portion 132P1b of the second underfill member 132b may fill a space between the second overhang portion OH2 and the substrate 110. The first portion 132P1b of the second underfill member 132b may support the second overhang portion OH2 to prevent occurrence of sagging and crack of the second chip SC2.

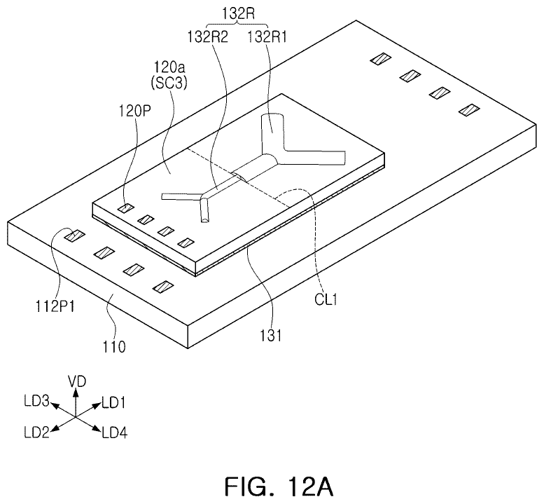

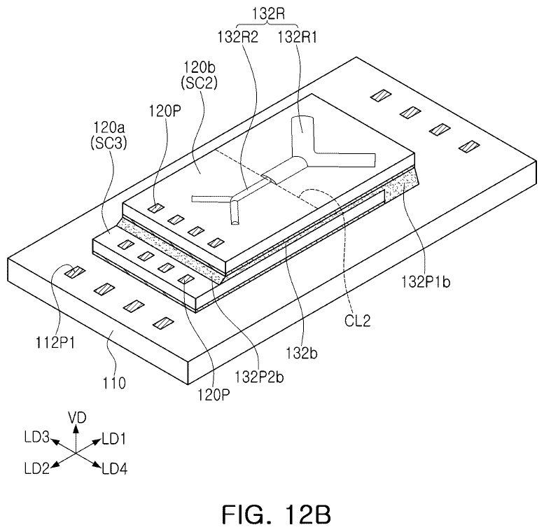

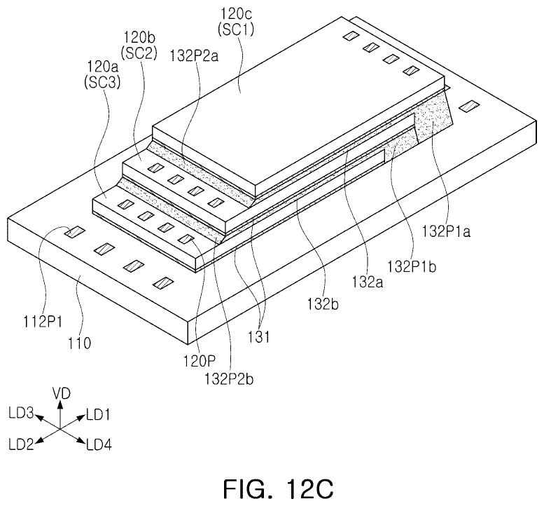

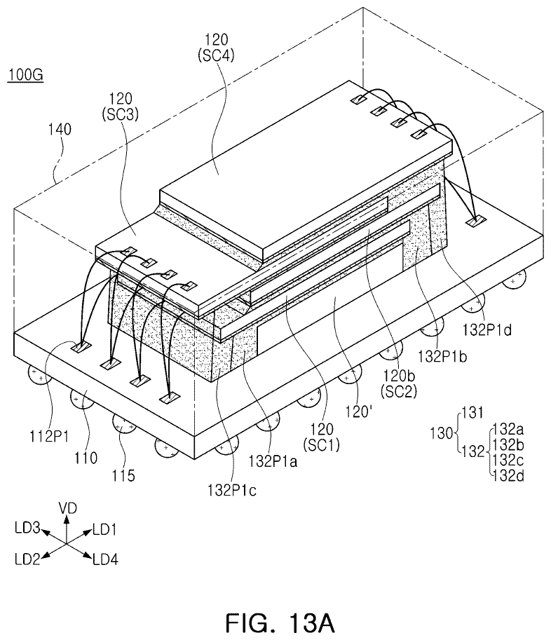

FIGS. 12A to 12C are views illustrating a method of manufacturing a semiconductor package 100F according to an example embodiment.

Referring to FIG. 12A, an adhesive material 132R may be applied on a first semiconductor chip 120a. The first semiconductor chip 120a may be the third chip SC3, as described with reference to FIGS. 11A and 11B. The adhesive material 132R may be applied by a process such as dispensing, jet printing, screen printing, or the like. The adhesive material 132R may be asymmetrically dispensed based on a first center line CL1 of the first semiconductor chip 120a. A first distribution portion 132R1 may include about 70% or more of the total amount of the adhesive material 132R dispensed.

Referring to FIG. 12B, a second semiconductor chip 120b may be attached on the first semiconductor chip 120a. The second semiconductor chip 120b may be the second chip SC2, as described with reference to FIGS. 11A and 11B. The second semiconductor chip 120b may have an overhang portion protruding in the first lateral direction LD1. The lower adhesive member 132b may be formed between the first semiconductor chip 120a and the second semiconductor chip 120b. The lower adhesive member 132b may include the first portion 132P1b extending in the first lateral direction LD1 and the second portion 132P2b extending in the second lateral direction LD2.

Subsequently, the adhesive material 132R may be applied onto the second semiconductor chip 120b. As described with reference to FIG. 12A, the adhesive material 132R may be asymmetrically dispensed relative to a second center line CL2 of the second semiconductor chip 120b. The first distribution portion 132R1 may include about 70% or more of a total distribution amount of the adhesive material 132R.

Referring to FIG. 12C, a third semiconductor chip 120c may be attached on the second semiconductor chip 120b. The third semiconductor chip 120c may be the first chip SC1, as described with reference to FIGS. 11A and 11B. The third semiconductor chip 120c may have an overhang portion protruding in the first lateral direction LD1. An upper adhesive member 132a may be formed between the second semiconductor chip 120b and the third semiconductor chip 120c. The upper adhesive member 132a may include a first portion 132P1a extending in the first lateral direction LD1, and a second portion 132P2a extending in the second lateral direction LD2. Thereafter, semiconductor chips may be further stacked, and then a wire bonding process, a molding process, or the like may be performed.

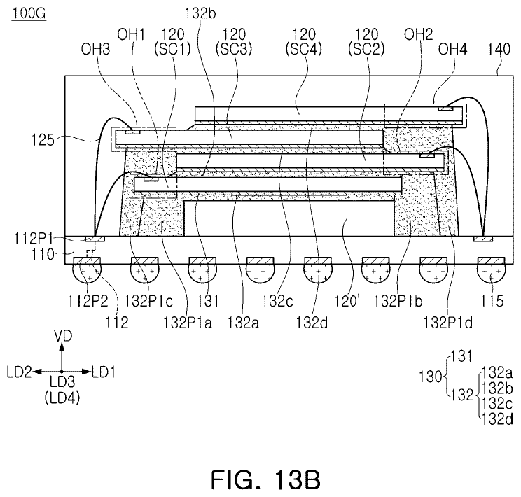

FIG. 13A is a perspective view of a semiconductor package 100G according to an example embodiment, and FIG. 13B is a cross-sectional side view of a semiconductor package 100G according to an example embodiment. For example, FIG. 13B illustrates the semiconductor package 100G of FIG. 13A as viewed from the third lateral direction LD3.

Referring to FIGS. 13A and 13B, in a semiconductor package 100G according to an example embodiment, a plurality of semiconductor chips 120 may be stacked in a zigzag shape. The semiconductor package 100G of the example embodiment may have the same or similar features as those described with reference to FIGS. 1A, 1B, 2, 3A, 3B, 3C, 4A, 4B, 4C, 4D, 5A, 5B, 6A, 6B, 7A, 7B, 8A, 8B, 8C,9A, 9B, 10A, 10B, 11A, 11B, 12A, 12B, and 12C, except for arrangement of the plurality of semiconductor chips 120. The plurality of semiconductor chips 120 may be disposed such that one side (hereinafter referred to as a “bonding edge”) on which a connection pad 120P is disposed may be staggered. The plurality of semiconductor chips 120 may be stacked such that respective bonding edges thereof alternately face both ends of a substrate 110. In some embodiments, each of the plurality of semiconductor chips 120 may include an overhang portion in which the connection pad 120P is disposed.

The plurality of semiconductor chips 120 may include a first chip SC1, a second chip SC2, a third chip SC3, and a fourth chip SC4, sequentially stacked in the vertical direction VD from the substrate 110. In an example embodiment, the plurality of semiconductor chips 120 may further include a spacer chip 120′ disposed between the first chip SC1 and the substrate 110. The spacer chip 120′ may be a silicon dummy that may be thicker than the other chips (SC1, SC2, SC3, and SC4), but is not limited thereto. The spacer chip 120′ may be attached to the substrate 110 by an adhesive film.

The first chip SC1 may include a first overhang portion OH1 protruding in the second lateral direction LD2 relative to the spacer chip 120'. The second chip SC2 may include a second overhang portion OH2 protruding in the first lateral direction LD1 relative to the spacer chip 120′ and the first chip SC1. The third chip SC3 may include a third overhang portion OH3 protruding in the second lateral direction LD2 relative to the second chip SC2. According to an embodiment, the third overhang portion OH3 may protrude in the second lateral direction LD2 relative to the first overhang portion OH1. The fourth chip SC4 may include a fourth overhang portion OH4 protruding in the first lateral direction LD1 relative to the third chip SC3. According to an embodiment, the fourth overhang portion OH4 may protrude in the first lateral direction LD1 relative to the second overhang portion OH2.

A second adhesive member 132 may include a first underfill member 132a between the spacer chip 120′ and the first chip SC1, a second underfill member 132b between the first chip SC1 and the second chip SC2, a third underfill member 132c between the second chip SC2 and the third chip SC3, and a fourth underfill member 132d between the third chip SC3 and the fourth chip SC4. The first underfill member 132a may include a first gapfill portion 132P1a extending onto the first overhang portion OH1. The second underfill member 132b may include a second gapfill portion 132P1b extending onto the second overhang portion OH2. The third underfill member 132c may include a third gapfill portion 132P1c extending onto the third overhang portion OH3. The fourth underfill member 132d may include a fourth gapfill portion 132P1d extending onto the fourth overhang portion OH4.

The first gapfill portion 132P1a may protrude in the second lateral direction LD2 relative to the spacer chip 120'. The first gapfill portion 132P1a may fill a space between the first overhang portion OH1 and the substrate 110. The first gapfill portion 132P1a may support the first overhang portion OH1 to prevent occurrence of sagging and crack of the first chip SC1.

The second gapfill portion 132P1b may protrude in the first lateral direction LD1 relative to the spacer chip 120′ and the first chip SC1. The second gapfill portion 132P1b may fill a space between the second overhang portion OH2 and the substrate 110. The second gapfill portion 132P1b may support the second overhang portion OH2 to prevent occurrence of sagging and crack of the second chip SC2.

The third gapfill portion 132P1c may protrude in the second lateral direction LD2 relative to the second chip SC2. The third gapfill portion 132P1c may fill a space between the third overhang portion OH3 and the first chip SC1. In some embodiments, the third gapfill portion 132P1c may protrude in the second lateral direction LD2 relative to the first chip SC1. The third gapfill portion 132P1c may fill a space between the third overhang portion OH3 and the substrate 110. The third gapfill portion 132P1c may support the third overhang portion OH3 to prevent occurrence of sagging and crack of the third chip SC3.

The fourth gapfill portion 132P1d may protrude in the first lateral direction LD1 relative to the third chip SC3. The fourth gapfill portion 132P1d may fill a space between the fourth overhang portion OH4 and the second chip SC2. In some embodiments, the fourth gapfill portion 132P1d may protrude in the first lateral direction LD1 relative to the second chip SC2. The fourth gapfill portion 132P1d may fill a space between the fourth overhang portion OH4 and the substrate 110. The fourth gapfill portion 132P1d may support the fourth overhang portion OH4 to prevent occurrence of sagging and crack of the fourth chip SC4.

According to embodiments, a semiconductor package with improved reliability may be provided by introducing an adhesive member supporting an overhang portion of a semiconductor chip and closely contacting surface curvature of the semiconductor chip.

An example embodiment provides a method for manufacturing a semiconductor package, including: disposing a first semiconductor chip on a substrate; applying a liquid adhesive onto the first semiconductor chip; disposing a second semiconductor chip to which a first adhesive member is attached on the first semiconductor chip, wherein the second semiconductor chip includes an overhang portion protruding in a first lateral direction, relative to the first semiconductor chip; and forming a second adhesive member from the liquid adhesive pressed by the second semiconductor chip, wherein the second adhesive member include a first portion extending onto the overhang portion of the second semiconductor chip, and a second portion extending opposite to the first portion.

An example embodiment provides a method for manufacturing a semiconductor package, wherein the liquid adhesive is asymmetrically distributed on an upper surface of the first semiconductor chip.

An example embodiment provides a method for manufacturing a semiconductor package, wherein the liquid adhesive includes a first distribution portion adjacent to the overhang portion, and a second distribution portion opposite to the first distribution portion.

An example embodiment provides a method for manufacturing a semiconductor package, wherein the first distribution portion includes about 70% to about 90% of a total distribution amount of the liquid adhesive.

An example embodiment provides a method for manufacturing a semiconductor package, wherein the second portion of the second adhesive member protrudes in a second lateral direction, opposite to the first lateral direction, relative to the second semiconductor chip.

An example embodiment provides a method for manufacturing a semiconductor package, wherein the first semiconductor chip includes a connection pad disposed to oppose the overhang portion, and the second portion of the second adhesive member is spaced apart from the connection pad of the first semiconductor chip.

An example embodiment provides a method for manufacturing a semiconductor package, wherein, after the forming a second adhesive member, a bonding wire connecting the first semiconductor chip and the substrate is formed.

According to an aspect of the present disclosure, a method of manufacturing a semiconductor package includes attaching a lower chip on a substrate, applying liquid adhesive on an upper surface of the lower chip, placing an upper chip on the upper surface of the lower chip with the liquid adhesive, wherein a first adhesive member is on a lower surface of the upper chip, shifting the upper chip in a first lateral direction parallel to and relative to an upper surface of the substrate, curing the liquid adhesive to form a second adhesive member between the first adhesive member and the lower chip, connecting a first wire to the lower chip and the substrate, and connecting a second wire to the upper chip. The applying of the liquid adhesive includes applying a first amount of the liquid adhesive to a first half of the upper surface of the lower chip, and applying a second amount of the liquid adhesive to a second half of the upper surface of the lower chip. The second amount is smaller than the first amount. The first half and the second half are divided using a center line extending along a straight line parallel to a direction parallel to the upper surface of the lower chip and perpendicular to the first lateral direction.

An example embodiment provides a method for manufacturing a semiconductor package, wherein in the applying of the liquid adhesive, the liquid adhesive is applied to form a Y-shape on the upper surface of the lower chip.

An example embodiment provides a method for manufacturing a semiconductor package, wherein the connecting of the first wire is performed before the applying of the liquid adhesive.

Various advantages and effects of the present inventive concept are not limited to the above-described contents, and will be more easily understood in the process of explaining specific embodiments.

While example embodiments have been illustrated and described above, it will be apparent to those skilled in the art that modifications and variations could be made without departing from the scope of the present inventive concept as defined by the appended claims.

What is claimed is:

1. A semiconductor package comprising:
a substrate;
a plurality of semiconductor chips stacked on the substrate in a vertical direction perpendicular to an upper surface of the substrate, wherein at least one chip among the plurality of semiconductor chips includes an overhang portion protruding in a lateral direction parallel to the upper surface of the substrate, relative to a lower chip disposed directly below the at least one chip;
a first adhesive member disposed on a lower surface of the at least one chip;
a second adhesive member including:
a center portion disposed between an upper surface of the lower chip and the first adhesive member,
a first portion extending onto the overhang portion of the at least one chip, and
a second portion extending opposite to the first portion, wherein the first portion is below the overhang portion and the center portion is between the first portion and the second portion; and
a bonding wire electrically connecting the plurality of semiconductor chips and the substrate.

2. The semiconductor package of claim 1,
wherein the first portion of the second adhesive member fills a gap between the overhang portion and the substrate.

3. The semiconductor package of claim 1,
wherein the overhang portion protrudes in a first lateral direction parallel to the upper surface of the substrate,
wherein the at least one chip has a first side surface defining one end of the overhang portion and a second side surface spaced apart from the first side surface in a second lateral direction, opposite to the first lateral direction, and
wherein the second portion of the second adhesive member protrudes in the second lateral direction, relative to the second side surface.

4. The semiconductor package of claim 3,
wherein a length of a lower surface of the first portion in the first lateral direction is greater than a length of a lower surface of the second portion in the second lateral direction.

5. The semiconductor package of claim 1,
wherein each of the first portion and the second portion of the second adhesive member has a side surface inclined in an outward direction.

6. The semiconductor package of claim 1,
wherein a maximum thickness of the first portion of the second adhesive member in the vertical direction is greater than a maximum thickness of the second portion of the second adhesive member in the vertical direction.

7. The semiconductor package of claim 1,
wherein each of the plurality of semiconductor chips includes a connection pad connected to a bonding pad of the substrate through the bonding wire,
wherein the lower chip includes an offset portion protruding opposite to the overhang portion, relative to the at least one chip, and
wherein the connection pad of the lower chip is disposed on the offset portion.

8. The semiconductor package of claim 7,
wherein the second portion of the second adhesive member is spaced apart from the connection pad of the lower chip.

9. The semiconductor package of claim 7,
wherein the second portion of the second adhesive member covers at least a portion of the connection pad of the lower chip.

10. The semiconductor package of claim 7,
wherein the connection pad of the at least one chip is disposed on the overhang portion.

11. The semiconductor package of claim 1,
wherein at least a portion of the upper surface of the lower chip includes a convex portion and a concave portion, and
wherein the second adhesive member fills a space on the concave portion.

12. The semiconductor package of claim 11,
wherein the first adhesive member contacts the convex portion.

13. The semiconductor package of claim 1,
wherein the second adhesive member further includes a third portion protruding, relative to the lower chip, in a direction parallel to the upper surface of the substrate and perpendicular to the lateral direction.

14. The semiconductor package of claim 13,
wherein the third portion of the second adhesive member contacts at least a portion of a side surface of the lower chip.

15. The semiconductor package of claim 1,
wherein the overhang portion extends beyond a side surface of the first portion in the lateral direction.

16. The semiconductor package of claim 1,
wherein the plurality of semiconductor chips include two or more lower chips stacked below the at least one chip, and
wherein the first portion of the second adhesive member contacts at least one side surface of each of the two or more lower chips.

17. A semiconductor package comprising:
a substrate;
a plurality of semiconductor chips stacked on the substrate in a vertical direction, wherein at least one chip among the plurality of semiconductor chips has a first side surface spaced apart in a first lateral direction, relative to a lower chip disposed directly below the at least one chip, and a second side surface spaced apart from the first side surface in a second lateral direction, opposite to the first lateral direction;
an adhesive member disposed between the lower chip and the at least one chip, and including a first portion protruding in the first lateral direction, relative to the lower chip, and a second portion protruding in the second lateral direction, relative to the at least one chip; and
a bonding wire electrically connecting the plurality of semiconductor chips and the substrate.

18. The semiconductor package of claim 17,
wherein the plurality of semiconductor chips include a first chip, a second chip directly below the first chip, and a third chip directly below the second chip,
the first chip has the first side surface and the second side surface relative to the second chip,
the second chip has the first side surface and the second side surface relative to the third chip,
the adhesive member includes an upper adhesive member disposed between the first chip and the second chip, and a lower adhesive member disposed between the second chip and the third chip,
the first portion of the upper adhesive member protrudes in the first lateral direction, relative to the second chip,
the first portion of the lower adhesive member protrudes in the first lateral direction, relative to the third chip,
the first portion of the upper adhesive member is in contact with the first side surface of the second chip and a side surface of the first portion of the lower adhesive member, and
the side surface of the first portion of the lower adhesive member is in contact with the first side surface of the third chip.

19. A semiconductor package comprising:
a substrate;
a plurality of semiconductor chips stacked on the substrate in a vertical direction perpendicular to an upper surface of the substrate, wherein at least one chip among the plurality of semiconductor chips includes an overhang portion protruding in a lateral direction parallel to the upper surface of the substrate, relative to a lower chip disposed directly below the at least one chip;
an attachment member disposed between the at least one chip and the lower chip;
an underfill member disposed between the attachment member and the lower chip, and extending onto the overhang portion of the at least one chip; and
a bonding wire electrically connecting the plurality of semiconductor chips and the substrate,
wherein the lower chip includes upper patterns and a passivation layer covering the upper patterns,
wherein at least a portion of a surface of the passivation layer includes a concave portion between the upper patterns, and
wherein the underfill member is disposed in the concave portion.

20. The semiconductor package of claim 19,
wherein the at least one chip includes:
a first chip including a first overhang portion protruding in a first lateral direction parallel to the upper surface of the substrate; and
a second chip including a second overhang portion protruding in a second lateral direction, opposite to the first lateral direction, and
wherein the underfill member includes:
a first underfill member below the first chip and extending onto the first overhang portion; and
a second underfill member below the second chip and extending onto the second overhang portion.
